(19) United States
(12) Patent Application Publication
(10) Pub. No.: US 2011/0142255 A1
(43) Pub. Date: Jun. 16, 2011

(54) SOUND PROCESSING APPARATUS AND METHOD

(75) Inventor: Atsushi Tanaka, Fuchu-shi (JP)

(73) Assignee: CANON KABUSHIKI KAISHA, Tokyo (JP)

(21) Appl. No.: 12/957,182

(22) Filed: Nov. 30, 2010

(30) Foreign Application Priority Data
Dec. 11, 2009 (JP) 2009-282218

(51) Int. Cl. H04B 15/00; H03G 3/00

(52) U.S. Cl. 381/94.1; 381/107

(57) ABSTRACT

A sound processing apparatus according to the present invention sets a volume value to a default value, outputs a pure tone signal of a predetermined frequency as a test signal from a loudspeaker, and acquires the output test signal using a microphone. When a signal level of a harmonic tone component of the acquired signal is equal to or greater than a threshold, the apparatus reduces the volume value so that the signal level equal to or greater than the threshold falls below the threshold and stores the reduced volume value. When outputting an acoustic signal, the apparatus adjusts a signal level of the acoustic signal at a stored frequency so that a product of a signal level at the stored frequency and a current volume value does not exceed a product of a signal level of the test signal and the stored volume value.

### BACKGROUND OF THE INVENTION

1. Field of the Invention

The present invention relates to a sound processing apparatus and a method, and in particular, to a technique for reducing noise in a listening room.

2. Description of the Related Art

Due to higher speeds and greater capacities recently achieved in digital technology, a music listening style has become popular in which songs are stored in a memory or the like, enabling music to be carried anywhere and listened to anywhere. On the other hand, a listening style where music is enjoyed through a sound apparatus installed in a living room or a listening room in a home also has a solid fan base. Apparatuses or the like that utilize digital technology to enable music to be appreciated in such listening rooms at better quality have become commercially available.

When listening to music in a listening room, phenomena attributable to characteristics of the room occur, such as a phenomenon referred to as a standing wave that is attributable to room size. A standing wave has an adverse effect in that depending on the position of the listener, reflections between the walls of a room cause the volume of a certain frequency to increase or to decrease, sometimes to an inaudible level.

In order to eliminate such adverse effects of a standing wave, for example, Japanese Patent Publication No. 60-1997 discloses a technique for applying a notch filter or the like to a frequency whose frequency response has a peak due to a standing wave in order to attenuate the frequency so as to prevent the frequency from peaking singularly. In addition, products are recently being marketed which utilize digital technology to automatically perform such filtering with a digital filter or the like.

In addition to resonance due to the aforementioned standing wave, factors detrimental to acoustic characteristics in a listening room include those attributable to resonance of materials, furniture, and the like in the room. For example, there are cases where a lighting fixture, a wall, a picture frame, a piece of furniture, or the like in the listening room resonates with a particular frequency and generates noise. Since the noise is caused by an object placed in the room or an object that is a constituent of the room instead of by the size of the room, conditions leading to the occurrence of the noise differ according to the configurations of rooms.

Unlike a standing wave, since the resonance phenomenon is not manifested as a peak or a dip with a particular frequency, a frequency thereof cannot be identified by simply looking at a frequency response. In addition, even if a frequency causing the noise is manually identified, by setting a notch filter at the frequency as described above, the noise-causing frequency is to always have a lower gain than an original signal and perceived as though sound of the portion corresponding to that frequency is missing. This is unfavorable in terms of the listening experience.

### SUMMARY OF THE INVENTION

The present invention reduces noise attributable to resonance generated by a wall, a piece of furniture, a piece of lighting equipment, or the like in a listening room without causing deterioration in sound quality with respect to listening experience.

According to one aspect of the present invention, there is provided a sound processing apparatus that adjusts, based on acoustic characteristics of a reproduced sound field, a frequency response of an acoustic signal to be output, the apparatus comprising: an outputting unit configured to output, in a state where a volume value that specifies a volume to be output from a loudspeaker is set to a default value, pure tone signals of a plurality of frequencies at respectively different timings as test signals from the loudspeaker; an acquiring unit configured to acquire the respective test signals output by the outputting unit from the loudspeaker using a microphone; a controlling unit configured to reduce the volume value for each of the signals acquired by the acquiring unit when a signal level of a harmonic tone component is equal to or greater than a threshold so that the signal level of the harmonic tone component falls below the threshold, and to store, in a storage unit, the reduced volume value in association with a frequency of a test signal corresponding to the signal in question; and an adjusting unit configured to adjust the signal level of the acoustic signal at the frequency stored in the storage unit so that when outputting the acoustic signal, a product of a signal level of the acoustic signal at the stored frequency and a current volume value does not exceed a product of a signal level of a test signal at the stored frequency and a volume value stored in the storage unit in association with the stored frequency.

Further features of the present invention will become apparent from the following description of exemplary embodiments (with reference to the attached drawings).

### BRIEF DESCRIPTION OF THE DRAWINGS

FIG. 1 is a diagram illustrating a schematic configuration of a sound system according to an embodiment.

FIG. 2 is a diagram illustrating an output acoustic signal and a frequency response of a recorded signal thereof.

FIG. 3 is a flowchart illustrating processing for identifying a noise-generating frequency and determining a volume value according to the embodiment.

FIG. 4 is a block diagram illustrating a configuration example of a sound processing apparatus according to the embodiment.

FIG. 5 is a block diagram illustrating a configuration example of a filter according to the embodiment.

FIG. 6 is a diagram illustrating characteristics of a limiter.

FIG. 7 is a diagram illustrating an example of signal processing in a frequency domain according to another embodiment.

FIG. 8 is a flowchart illustrating processing for identifying a noise-generating frequency and determining a volume value according to the other embodiment.

### DESCRIPTION OF THE EMBODIMENTS

Hereinafter, preferred embodiments of the present invention will be described in detail with reference to the drawings.

### First Embodiment

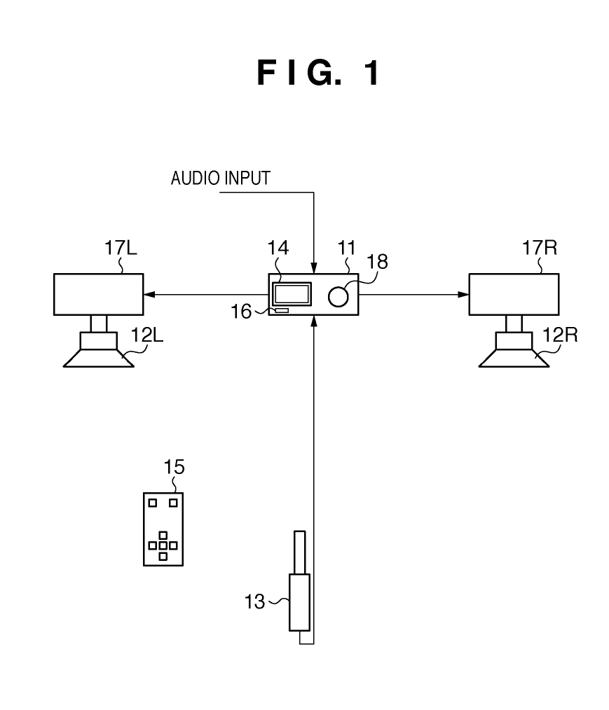

FIG. 1 is a diagram illustrating a configuration of a sound system according to the present embodiment. Due to the configuration and processing described below, the sound system is capable of adjusting, based on acoustic characteristics of a listening room that is a reproduced sound field, a frequency response of an acoustic signal to be output.

Reference numeral 11 denotes a sound processing apparatus that includes a displaying unit 14, a volume control 18, a remote control signal receiving unit 16, and the like. An audio signal is transmitted from the sound processing apparatus 11 to loudspeakers 12L and 12R.

Loudspeakers 12L and 12R are active speakers respectively including power amplifiers 17L and 17R. The configuration is but an example and an audio system of a type having a midway power amplifier instead of an active speaker may alternatively be adopted.

Reference numeral 13 denotes a microphone that is used to acquire a test signal or the like sent from the sound processing apparatus 11 to the loudspeakers 12L and 12R. Reference numeral 15 denotes a remote controller for controlling the sound processing apparatus 11. The remote controller 15 is normally used to select an audio device (CD, DVD, or the like, not shown) connected to the sound processing apparatus 11, or to perform volume control. While a volume value that specifies a volume to be output can be manually set by a user using the volume control 18 or the remote controller 15, the present configuration also enables a volume value to be automatically set by the system. Known techniques can be adopted for volume value adjustment which may either be applied to a digital signal or an analog signal of an acoustic signal to be output.

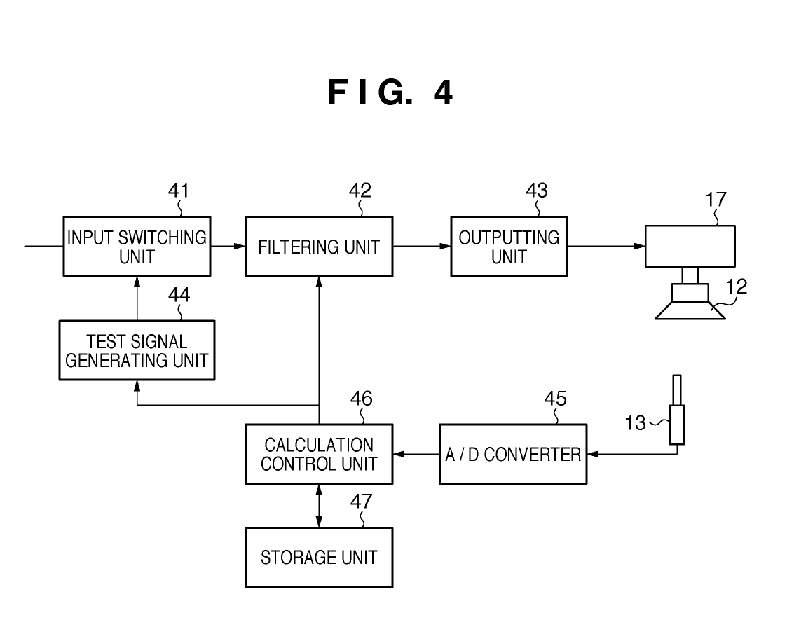

FIG. 4 illustrates a block diagram of a configuration of the sound processing apparatus 11. During normal operation, music information from an external acoustic device connected to an input switching unit 41 is sent to an outputting unit 43 via a filter 42. With an apparatus having a LINEOUT, the outputting unit 43 outputs music information in analog using a D/A converter, not shown. On the other hand, in the case of a digital output, an output signal is converted into a digital IF signal such as SPDIF to output music information to the loudspeakers 12.

During an operation for determining a correction coefficient, the input switching unit 41 is connected to a test signal generating unit 44 according to an instruction from a calculation control unit 46. A sweep signal having a frequency that continuously varies from a low frequency to a high frequency, white noise, and the like can be output from the test signal generating unit 44. Alternatively, a signal using an MLS (maximum length sequence) signal, in turn using an M-sequence signal that is a type of a pseudo-random signal, can be output. Moreover, a sine wave signal with a plurality of specific frequencies can also be output.

The microphone 13 acquires a test signal generated from the loudspeakers 12. When the microphone 13 is connected to the sound processing apparatus 11, recorded data is converted by an A/D converter 45 into digital data to be sent to the calculation control unit 46 and, for example, recorded in a storage unit 47 and analyzed according to a program by the calculation control unit 46.

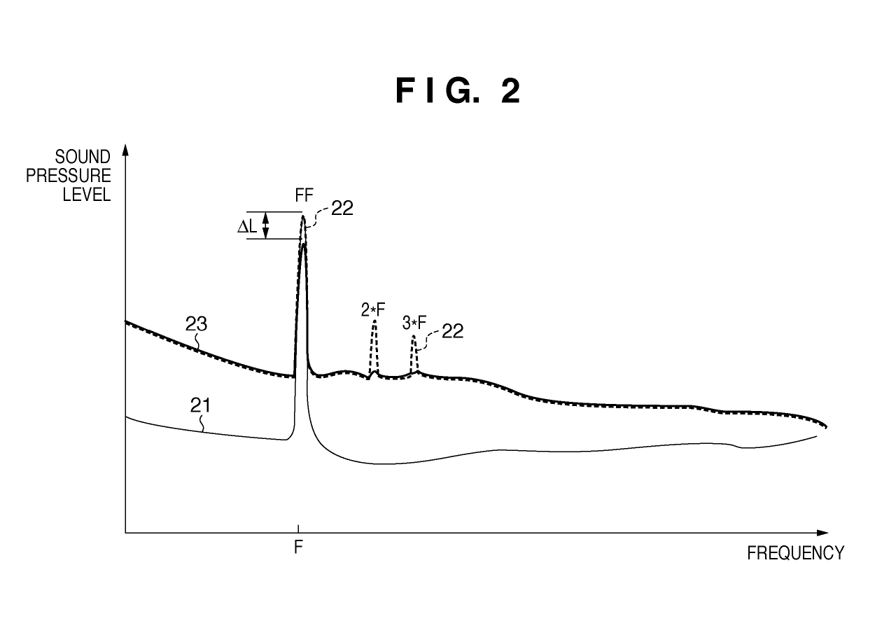

FIG. 2 is a diagram illustrating data transformed into a frequency spectrum by FFT or the like of a pure tone signal (sine wave) of a given frequency generated and recorded as a test signal in a state where the microphone 13 is connected. In FIG. 2, reference numeral 21 denotes a spectrum of the pure tone signal as a test signal. In this example, a peak occurs at a fundamental frequency F.

Characteristic 22 denotes a spectrum of a signal obtained by emitting the signal from the loudspeakers 12 at a volume value V1 and acquiring the signal using a microphone. It is shown that the signal includes a signal having peaks at harmonic tone frequencies of 2×F and 3×F in addition to the fundamental frequency F. Since the output test signal is a sine wave signal that only includes the fundamental frequency F, under normal circumstances, a spectrum should only be observed at the frequency F in the acquired signal as well. Assuming that lines of the loudspeakers, the amplifier and the like are free of distortion, the signal of the N-harmonic tones is conceivably a noise component generated by a resonance occurring somewhere in the listening room.

In FIG. 2, reference numeral 23 denotes a spectrum when the volume of the test signal is reduced by ΔL. As is apparent, the signal peaks at 2×F and 3×F are either equal to or below a background noise level or not observed. Therefore, it is found that noise such as a resonance of a room is generated accompanied with noise having an N-harmonic tone frequency by a material, a piece of furniture, or the like in the room that resonates to a specific frequency when sound pressure of the resonant frequency is equal to or greater than a given level. The present invention has been made in consideration thereto in order to prevent noise due to resonance. Specifically, by identifying a maximum sound pressure where noise due to resonance is not generated at a specific frequency and providing a filter that keeps the sound pressure of the frequency under the maximum sound pressure, resonant noise is prevented or reduced.

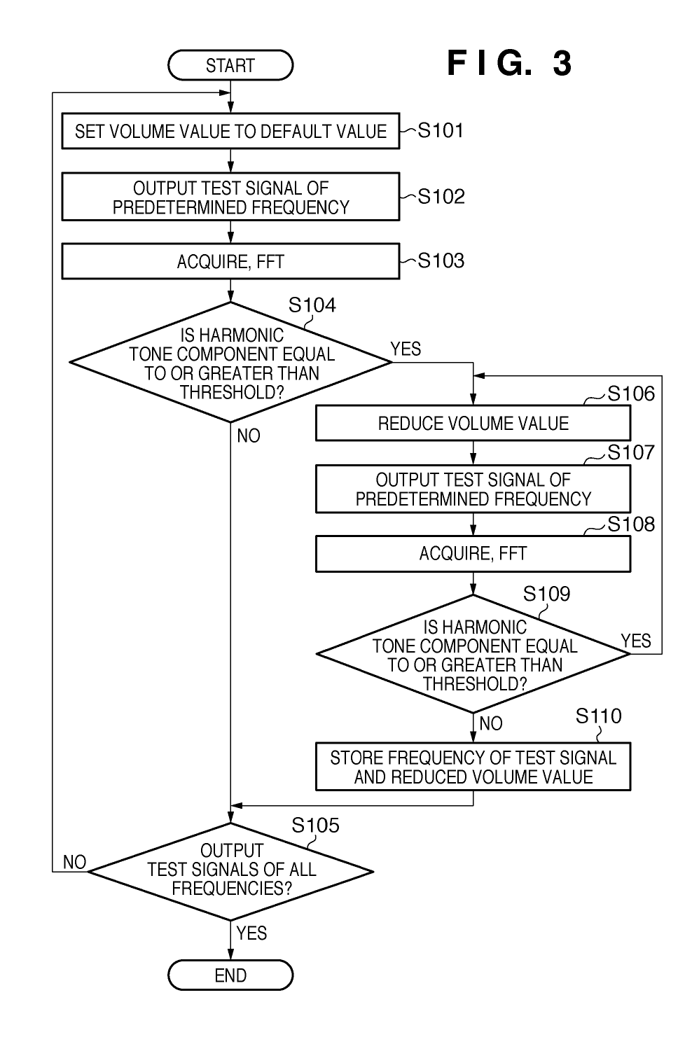

FIG. 3 is a flowchart illustrating processing for searching for a frequency where noise due to resonance is generated and determining a volume corresponding to the noise-generating frequency according to the present embodiment. For example, the present processing starts upon receiving a mode shifting instruction from the remote controller 15 or the like and shifting from a normal music reproduction mode to a correction mode. In this case, an instruction to connect the microphone 13 to the sound processing apparatus 11 is to be displayed on the displaying unit 14 or the like.

First, the volume value is set to a default value (S101). The default value is to be set to a certain volume value such as a normally used volume value. In S102, a pure tone signal of a predetermined frequency among a plurality of pure tone signals with different frequencies is output as a test signal from the loudspeakers 12. The signal is recorded using the microphone 13 (S103). The recorded data is transformed into spectrum information by FFT or the like. A determination is made on whether or not sound pressure levels (signal levels) of N-harmonic tone components (for example, second harmonic tone, third harmonic tone) among the transformed spectrum information are respectively equal to or higher than a threshold expressed as background noise level+α[dB] (S104). Measurement of background noise is to be performed in an initial state in the correction mode after confirming that the microphone has been connected. The value of +α may be determined based on an S/N of the system or arranged so as to be user-settable.

When the signal levels of the N-harmonic tones are under background noise level+α[dB], it is determined that a resonance of the room has not occurred with respect to the test signal. In this case, the flow proceeds to S105.

When the signal levels of the N-harmonic tones are equal to or greater than background noise level+α[dB], it is determined that a resonance of the room has occurred with respect to the test signal. In this case, the current volume value is reduced by a predetermined value (S106), and the same test signal is output from the loudspeakers 12 at the reduced volume value (S107). The signal is recorded using the microphone 13 (S108). The recorded data is subjected to spectrum transform by FFT or the like. Subsequently, signal levels (noise levels) of N-harmonic tone components (for example, second harmonic tone, third harmonic tone) among the spectrum are compared with the threshold (background noise level+α) (S109), and when the signal levels are equal to or higher than the threshold, the flow returns to S106 to have the processing be repeated after further lowering the volume value. When the noise level falls below the threshold in S109, the volume value at that point is stored in association with the frequency (fundamental frequency) of the test signal (S110).

After S104 or S110 is concluded, a determination is made on whether or not test signals of all target frequencies have been output (S105). When there is a test signal yet to be output, the flow returns to S101 to have the processing be repeated after changing to a test signal of a subsequent frequency.

In this manner, with the loop from S101 to S105, in S101, a plurality of pure tone signals of different frequencies in a predetermined frequency range is to be output from a loudspeaker as test signals at respectively different timings. An interval of the respective frequencies may be set to, for example, every 1 [Hz] or to ⅓ or ⅙ octave bandwidths. Alternatively, the interval may be set to a frequency of a musical scale. The interval can be set along with specifications of the system. The predetermined frequency range may be configured so as to be settable in advance to focus on a low range, to include up to an intermediate range, or the like. Obviously, the frequency range may alternatively include the entire audible range.

When measurements of test signals of all frequencies have been concluded (S105), the correction mode is terminated. At this point, it is possible to display that the correction mode has been concluded on the displaying unit 14. The determined maximum value is set to the filter 42.

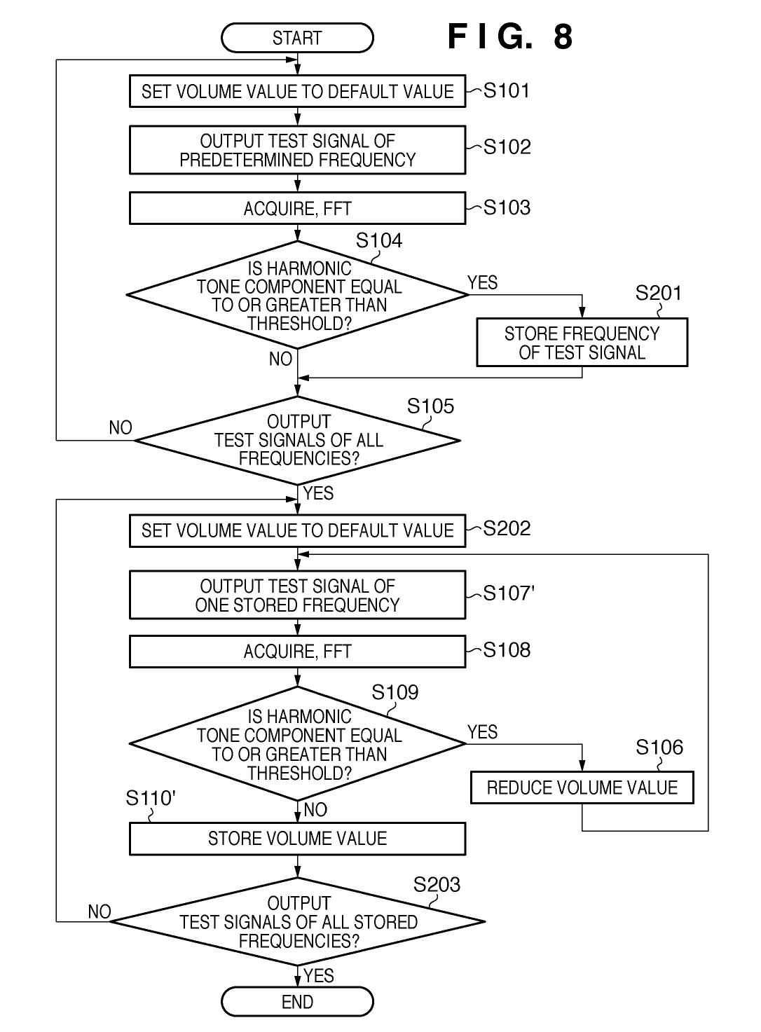

Moreover, the processing described above may be modified to, for example, a flow illustrated in FIG. 8. In FIG. 8, like reference characters denote processing steps whose contents are the same as the processing steps illustrated in FIG. 3. Hereinafter, differences from the flow illustrated in FIG. 3 will be briefly described.

In the flow illustrated in FIG. 8, when it is determined in step S104 that a harmonic tone component is equal to or greater than the threshold, the value of the frequency of the corresponding test signal is stored in the storage unit 47 (S201). In this manner, test signals of all frequencies are first measured, and a value of the frequency of the test signal is stored when the harmonic tone component thereof is equal to or greater than the threshold.

Next, after setting the volume value to the default value in S202, the flow proceeds to S107′. Although similar to the processing in S107, in S107′, a pure tone signal of one of the frequencies stored in S201 as frequencies where resonance occurs is once again output from the loudspeakers 12 as a test signal. In addition, in S110′, a volume value at which a harmonic tone component falls below the threshold is stored in association with the frequency of the corresponding test signal already stored in the storage unit 47. In S203, a determination is made on whether or not test signals of all frequencies stored in the storage unit 47 have been output.

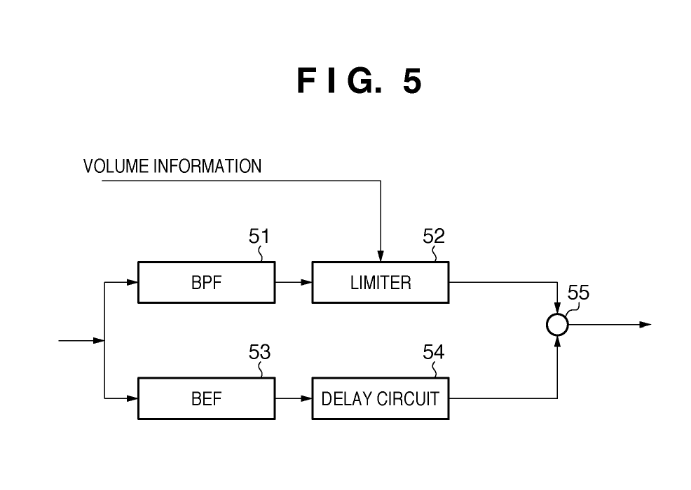

Next, operations of the filter 42 when outputting an input acoustic signal will be described. FIG. 5 is a block diagram illustrating a configuration example of the filter 42. In the diagram, reference numeral 51 denotes a bandpass filter (BPF) which discriminates the aforementioned frequency at which a resonance is judged to occur and which extracts a signal at the resonance-occurring frequency from the input acoustic signal. Reference numeral 52 denotes an amplitude-limiting limiter which judges whether or not a signal passed by the BPF 51 exceeds a maximum value and which controls the signal level so that the maximum value is not exceeded. In this case, a current volume value is also input to the limiter 52 from the calculation control unit 46 or other hardware. For example, even when an input signal has a large value, a sound pressure level capable of causing resonance is not reached if the current volume value is low. Conversely, even when an input value is small, if the current volume value is set to a large value, a resonance occurs. In consideration thereof, in the present embodiment, the threshold is determined as, for example, a product of a signal level and a current volume value. Therefore, a current volume value is input to the limiter 52.

If SL denotes a signal level and VL denotes a current volume value, then a threshold Pth is obtained as a product of SL and VL. The limiter 52 stores a product of the maximum volume obtained in the correction mode described earlier and the level of a corresponding test signal as a peak level. Subsequently, the signal is controlled so that the product of the signal level of a discriminated frequency and the current volume value is equal to or lower than the peak level. In addition, a band elimination filter (BEF) 53 eliminates a component of the discriminated frequency from the original audio signal. Subsequently, a delay circuit 54 delays an output signal of the BEF 53 so that the timing of the output signal coincides with the timing of a signal output from the limiter 52. A synthesizing unit 55 synthesizes and outputs the signal output from the limiter 52 and the output signal of the delay circuit 54.

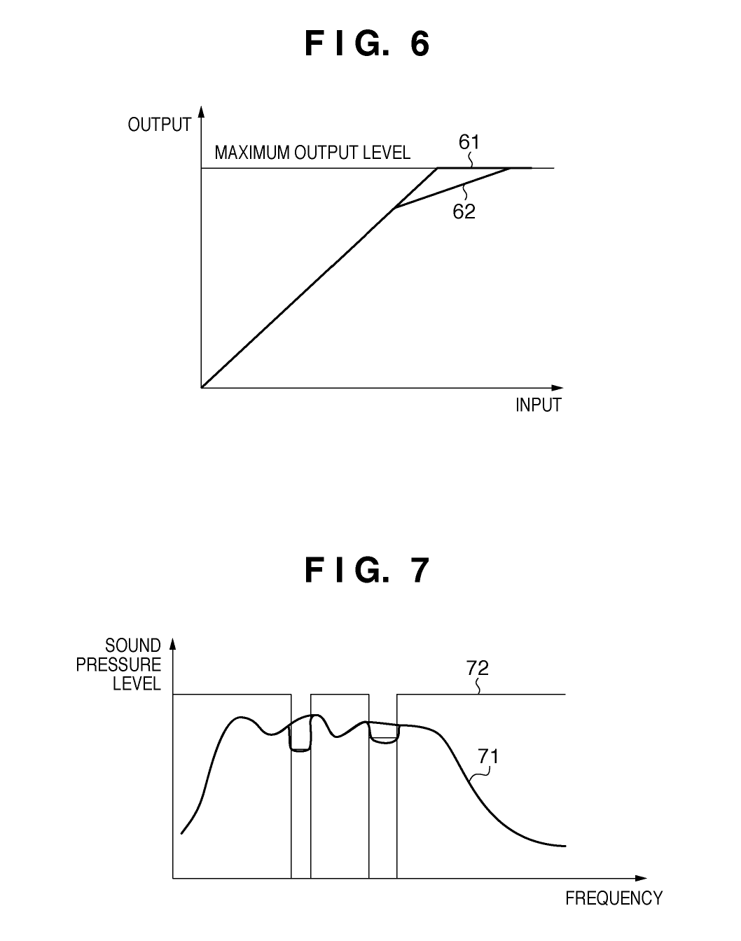

Moreover, while the limiter 52 that adjusts input signal levels may be configured so as to slice levels equal to or higher than a specific level, a configuration such as a so-called compressor whose suppression characteristics vary depending on sound pressure may alternatively be adopted to achieve a more natural listening experience. Slicing refers to a configuration for clipping a peak level so that a certain level is not reached or exceeded as indicated by reference numeral 61 in FIG. 6. A compressor refers to a device for attenuating sound pressure equal to or greater than a certain level as indicated by reference numeral 62 in FIG. 6.

### Second Embodiment

While the first embodiment described above is configured so as to discriminate frequencies using a bandpass filter and the like and apply a limiter to the frequencies, filtering may alternatively be performed using a method in which an acoustic signal to be output is transformed into a frequency-domain signal and value limiting is only applied to corresponding frequencies.

For example, an output object acoustic signal expressed as a time-domain signal is transformed into a frequency-domain signal using an FFT or the like. Next, a first product of a signal level of the acoustic signal at the frequency stored in S104 and the current volume value is compared with a second product of a signal level of a test signal (pure tone signal) of the frequency stored in S104 and the volume value stored in association with the stored frequency. At this point, if the first product is greater than the second product, a spectrum value of the frequency-domain signal at the stored frequency is reduced so that the first product equals or falls below the second product. For example, as illustrated in FIG. 7, when an input signal has a frequency response 71, the frequency response 71 is compared with characteristics of a mask 72 with respect to a maximum value of each resonant frequency. If a signal level is greater than the masking level, the value is reduced to the masking level. Subsequently, the frequency-domain signal is inverse-transformed into a time-domain signal using IFFT or the like to be output. Adopting such a configuration enables filtering such as BPF and BEF to be processed simultaneously and also enables the amount of calculation to be reduced.

While the above embodiments have been described in terms of modules such as a hardware configuration, respective acoustic processing portions can alternatively be processed by software using a digital signal processor (DSP) or the like.

### Other Embodiments

Aspects of the present invention can also be realized by a computer of a system or apparatus (or devices such as a CPU or MPU) that reads out and executes a program recorded on a memory device to perform the functions of the above-described embodiment(s), and by a method, the steps of which are performed by a computer of a system or apparatus by, for example, reading out and executing a program recorded on a memory device to perform the functions of the above-described embodiment(s). For this purpose, the program is provided to the computer for example via a network or from a recording medium of various types serving as the memory device (e.g., computer-readable medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-282218, filed Dec. 11, 2009, which is hereby incorporated by reference herein in its entirety.

What is claimed is:

1. A sound processing apparatus that adjusts, based on acoustic characteristics of a reproduced sound field, a frequency response of an acoustic signal to be output, the apparatus comprising:
an outputting unit configured to output, in a state where a volume value that specifies a volume to be output from a loudspeaker is set to a default value, pure tone signals of a plurality of frequencies at respectively different timings as test signals from the loudspeaker;
an acquiring unit configured to acquire the respective test signals output by said outputting unit from the loudspeaker using a microphone;
a controlling unit configured to reduce the volume value for each of the signals acquired by said acquiring unit when a signal level of a harmonic tone component is equal to or greater than a threshold so that the signal level of the harmonic tone component falls below the threshold, and to store, in a storage unit, the reduced volume value in association with a frequency of a test signal corresponding to the signal in question; and
an adjusting unit configured to adjust the signal level of the acoustic signal at the frequency stored in said storage unit so that when outputting the acoustic signal, a product of a signal level of the acoustic signal at the stored frequency and a current volume value does not exceed a product of a signal level of a test signal at the stored frequency and a volume value stored in said storage unit in association with the stored frequency.

2. The apparatus according to claim 1, wherein said adjusting unit comprises:
a bandpass filter configured to pass only a component of a frequency stored in said storage unit among the acoustic signal;
a limiter configured to set a product of a signal level of the test signal at the frequency stored in said storage unit and a volume value stored in association with the stored frequency as a peak value and limit a signal level of the acoustic signal so that a product of a signal level of a signal passed through said bandpass filter and a current volume value is equal to or lower than the peak level;
a band elimination filter configured to eliminate a component of the frequency stored in said storage unit of the acoustic signal;
a delay circuit configured to delay an output signal of said band elimination filter so that the timing of the output signal coincides with the timing of a signal output from said limiter; and
a synthesizing unit configured to synthesize an output signal of said limiter and an output signal of said delay circuit and output an acoustic signal whose signal level at the frequency stored in said storage unit has been adjusted.

3. The apparatus according to claim 1, wherein said adjusting unit comprises:
a transform unit configured to transform the acoustic signal into a frequency-domain signal;
a reducing unit configured to reduce a spectrum value of the frequency-domain signal at a frequency of the acoustic signal stored in said storage unit when a first product of a signal level of the acoustic signal at the frequency stored in said storage unit and a current volume value is greater than a second product of the signal level of the test signal at the frequency stored in said storage unit and a volume value stored in association with the stored frequency so that the first product equals or falls below the second product; and
an inverse-transform unit configured to transform the frequency-domain signal after a spectrum value thereof has been adjusted by said reducing unit into a time-domain signal.

4. A sound processing method for adjusting a frequency response of an acoustic signal to be output based on acoustic characteristics of a reproduced sound field output, the method comprising the steps of:
outputting, in a state where a volume value that specifies a volume to be output from a loudspeaker is set to a default value, pure tone signals of a plurality of frequencies at respectively different timings as test signals from the loudspeaker;
acquiring the respective output test signals from the loudspeaker using a microphone;
reducing the volume value for each of the acquired signals when a signal level of a harmonic tone component is equal to or greater than a threshold so that the signal level of the harmonic tone component falls below the threshold, and for storing, in a memory, the reduced volume value in association with a frequency of a test signal corresponding to the signal in question; and
adjusting the signal level of the acoustic signal at the frequency stored in the memory so that when outputting the acoustic signal, a product of a signal level of the acoustic signal at the stored frequency and a current volume value does not exceed a product of a signal level of a test signal at the stored frequency and a volume value stored in the memory in association with the stored frequency.

5. A non-transitory computer-readable storage medium storing a program that enables a computer to function as respective unit included in the sound processing apparatus according to claim 1.
